(19) United States
(12) Patent Application Publication
(10) Pub. No.: US 2025/0003109 A1
(43) Pub. Date: Jan. 2, 2025

(54) On-site Growth of Halide Perovskite Micro and Nanocrystals

(71) Applicant: Massachusetts Institute of Technology, Cambridge, MA (US)

(72) Inventors: Farnaz Niroui, Cambridge, MA (US); Patricia Jastrzebska-Perfect, Cambridge, MA (US)

(21) Appl. No.: 18/708,364

(22) PCT Filed: Nov. 29, 2022
(86) PCT No.: PCT/US2022/051236

§ 371 Date: May 8, 2024

Related U.S. Application Data
(60) Provisional application No. 63/284,554, filed on Nov. 30, 2021.

(51) Int. Cl. C30B 7/06; C30B 29/12; G03F 7/075; G03F 7/38; H01L 33/00

(52) U.S. Cl. CPC C30B 7/06; C30B 29/12; G03F 7/0755; G03F 7/38; H01L 33/005

(57) ABSTRACT

A system and method for patterned growth of halide perovskite nanocrystals is disclosed. This method allows control over the size, number and position of the nanocrystals, while ensuring compatibility with device integration processes. The method uses a topographical template comprising a plurality of wells with asymmetric surface wetting to confine the nanocrystal growth to within the wells. Further, the shape and surface wetting properties of the wells are used to induce local directional forces to guide nanocrystal positioning during the growth process. With this technique, scalable arrays of nanocrystals with tunable dimensions and precise positional accuracy are possible. As an example, this method allows arrays of active nanoscale perovskite light emitting diodes (LEDs).

This application claims priority to U.S. Provisional Patent Application Ser. No. 63/284,554, filed Nov. 30, 2021, the disclosure of which is incorporated by reference in its entirety.

### FIELD

Embodiments of the present disclosure relate to a method of on-site growth of crystals, and more particularly, halide perovskite micro and nanocrystals.

### BACKGROUND

The ability to form crystals in predetermined locations on a substrate has important applications. One such class of material is referred to as perovskite materials. For example, in certain embodiments, these crystals may have optoelectronic properties. One such crystal is halide perovskite (APbX₃ where A is an organic or inorganic cation, and X is a halide). Thus, the formation of crystals in predetermined locations may enable the creation of arrays of very small LEDs, lasers, memristors, transistors, single photon sources and other similar applications.

However, the use of crystals is not limited to these halide perovskites. There may be other perovskites that may be of interest as well. The ability to precisely position these crystals at the nanoscale with high spatial control can extend prospects of these materials to on-chip integrated nanodevices.

Many of these perovskite materials degrade rapidly, making them incompatible with conventional lithographic processes.

Therefore, it would be beneficial if there was a system and method of growing these nanocrystals in situ on the desired site. Further, it would be advantageous if the size and position of these nanocrystals could be controlled.

### SUMMARY

A system and method for patterned growth of halide perovskite nanocrystals is disclosed. This method allows control over the size, number and position of the nanocrystals, while ensuring compatibility with device integration processes. The method uses a topographical template comprising a plurality of wells with asymmetric surface wetting to confine the nanocrystal growth to within the wells. Further, the shape and surface wetting properties of the wells are used to induce local directional forces to guide nanocrystal positioning during the growth process. With this technique, scalable arrays of nanocrystals with tunable dimensions and precise positional accuracy are possible. As an example, this method allows arrays of active nanoscale perovskite light emitting diodes (LEDs).

According to one embodiment, a method of producing perovskite crystals in-situ is disclosed. The method comprises creating an asymmetrically wetting template on a surface, wherein the template comprises a plurality of wells; and disposing a perovskite precursor solution comprising a metal halide perovskite in the plurality of wells; wherein, after evaporation, a perovskite crystal is disposed in one or more of the plurality of wells. In some embodiments, the perovskite precursor solution comprises perovskite precursor ions dissolved in a solvent. In certain embodiments, the perovskite precursor solution further comprises ligands that passivate the surface of the perovskite crystal or polymers that encapsulate particles during formation. In some embodiments, the asymmetrically wetting template comprises a lyophobic surface. In some embodiments, the lyophobic surface is formed by exposing the template to a first functionalization step using self-assembled fluorinated molecular monolayers. In some embodiments, the plurality of wells are lyophilic. In certain embodiments, a degree of lyophilicity of the plurality of wells is tuned by exposure to a second functionalization step using self-assembled fluorinated molecular monolayers. In some embodiments, the wells are shaped such that the perovskite crystal preferentially forms at a predetermined location within the wells. In some embodiments, the asymmetrically wetting template is created by: applying a resist to the surface; exposing the resist; performing a first functionalization step using self-assembled fluorinated molecular monolayers on the exposed resist; and developing the resist to create the plurality of wells, wherein a top surface of the resist is lyophobic. In other embodiments, the asymmetrically wetting template is created by: applying a first resist to the surface; applying a second resist on the first resist; patterning the first resist and second resist to create a plurality of pillars; depositing a dielectric material in spaces between the pillars; plurality of performing a first functionalization step using self-assembled fluorinated molecular monolayers on the dielectric material and the plurality of pillars; and lifting off the plurality of pillars; wherein, after the lifting off, the dielectric material has the plurality of wells and a lyophobic top surface.

According to another embodiment, a method of fabricating an LED array is disclosed. The method comprises creating an asymmetrically wetting template on a substrate, wherein the template comprises a plurality of wells; disposing a perovskite precursor solution comprising a metal halide perovskite in the plurality of wells; wherein, after evaporation, a perovskite nanocrystal is disposed in one or more of the plurality of wells; applying an electron transport layer after the perovskite nanocrystal is formed; and disposing a conductive layer on the electron transport layer. In some embodiments, the substrate comprises indium tin oxide on glass. In some embodiments, the template comprises silicon dioxide.

According to another embodiment, a method of producing nano or microcrystals in-situ is disclosed. The method comprises creating an asymmetrically wetting template on a surface, wherein the template comprises a plurality of wells; and disposing a precursor solution comprising precursor ions in a solvent in the plurality of wells; wherein, after evaporation, the nano or microcrystal is disposed in one or more of the plurality of wells. In some embodiments, the asymmetrically wetting template comprises a lyophobic surface. In certain embodiments, the lyophobic surface is formed by exposing the template to a first functionalization step using self-assembled fluorinated molecular monolayers. In some embodiments, the plurality of wells are lyophilic. In certain embodiments, a degree of lyophilicity of the plurality of wells is tuned by exposure to a second functionalization step using self-assembled fluorinated molecular monolayers. In some embodiments, the wells are shaped such that the nano or microcrystal preferentially forms at a predetermined location within the well. In some embodiments, the template comprises a resist, a dielectric material or a metal.

### BRIEF DESCRIPTION OF THE FIGURES

For a better understanding of the present disclosure, reference is made to the accompanying drawings, which are incorporated herein by reference and in which:

FIGS. 1A-1D shows the crystal growth scheme of perovskite nanocrystals using asymmetrically wetting templates according to one embodiment;

FIGS. 2A-2F show the process for creating the template 60 according to one embodiment;

FIGS. 3A-3H show the process for creating the template 60 according to a second embodiment;

FIG. 4A-4C show the process of creating a two dimensional template;

FIG. 5A shows SEM images of example perovskite nanocrystals made using the process shown in FIGS. 1A-1D;

FIG. 5B shows a photoluminescence (PL) map of an array of perovskite nanocrystals;

FIG. 5C shows a PL spectrum of an example nanocrystal;

FIG. 6 shows the calculation of the critical contact angle;

FIG. 7 shows the crystal placement for a triangular well;

FIG. 8 shows a tear drop shaped well; and

FIG. 9 shows a cross-sectional view of a LED device according to one embodiment.

### DETAILED DESCRIPTION

This disclosure describes a technique for growing deterministically positioned perovskite crystals in-situ. The technique employs surface-functionalized topographical templates to locally confine perovskite precursor solution that is deposited onto the template within defined locations. The templates comprise lyophilic wells of defined morphologies lithographically patterned into a lyophobic surface. The surface functionalization and topography of templates enables primary confinement of precursor solution after deposition, such that the precursor solution wets and adheres to lyophilic interiors of wells. Thus, the precursor solution deposits within the wells, without wetting or adhering to the surfaces. The morphology of wells then provides secondary confinement of precursor solution, ensuring precursor solution retreats to a specific location within the well during solvent evaporation for single nucleation. Since surface topographic patterning and functionalization is achieved through lithography, this technique can allow for growth of perovskite crystals directly on prefabricated structures and is compatible with arbitrary surfaces and designs.

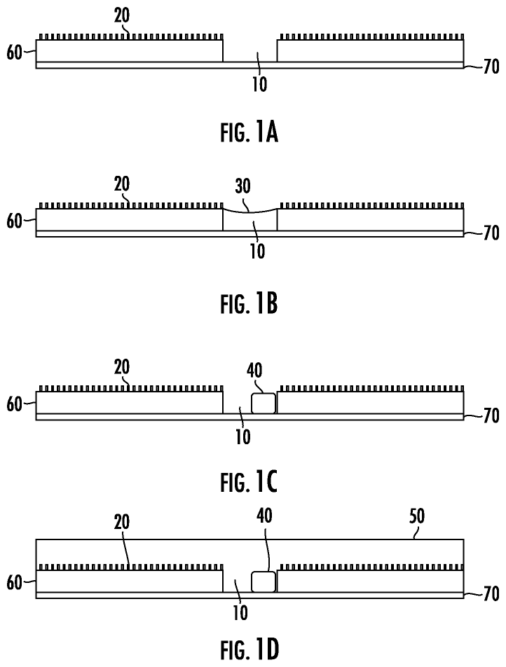

FIGS. 1A-1D demonstrates how an asymmetrically wetting template enables controlled growth of perovskite nanocrystals. The fabrication processes enabling crystal growth are shown in these figures. In this example scheme, as shown in FIG. 1A, the template 60 comprises one or more lyophilic wells 10 patterned in a lyophobic surface 20, which may be the surface of a resist and a different material. The template may be disposed on a surface 70.

As seen in FIG. 1B, perovskite precursor solution 30 is deposited on the template 60 by spin-coating or blade-coating. This process can be performed in an inert environment, such as a nitrogen or argon filled glove box, for increased material stability. The precursor solution 30 comprises perovskite precursor ions dissolved in a solvent. In one embodiment, the precursor solution comprises PbBr₂ and CsBr dissolved in dimethyl sulfoxide (DMSO). In some embodiments, the perovskite precursor solution 30 is spin-coated onto the template 60. Combined surface topography and surface wetting forces the liquid to remain trapped inside the wells 10. The precursor solution 30 selectively wets lyophilic regions to localize the growth volume, such that upon slow evaporation of solvent, a crystal 40 nucleates, as shown in FIG. 1C. The precursor solution 30 may also contain ligands that will passivate the surface of the perovskite crystal, or polymers that will encapsulate the particles during or after formation. The size of the perovskite crystal 40 is controlled through the volume and concentration of precursor solution 30 confined within the template 60. After perovskite growth, the perovskite crystals 40 can be further engineered in properties through surface modifications or encapsulated by deposition of an encapsulate 50, as shown in FIG. 1D. The encapsulate 50 may be a polymer, ligand, or dielectric layer deposited using solution- or vapor-phase processes. The post-synthesis encapsulant 50 is chosen so that it does not dissolve or damage the nanocrystals during deposition and remains impermeable to moisture after deposition.

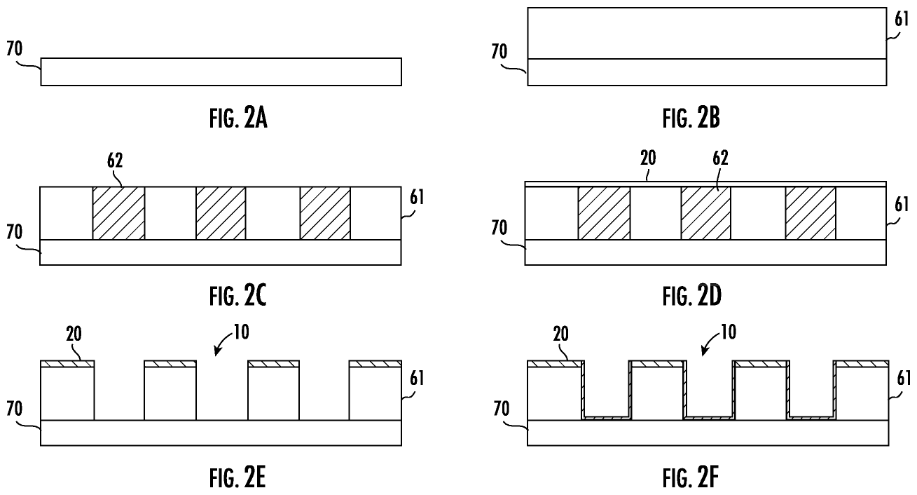

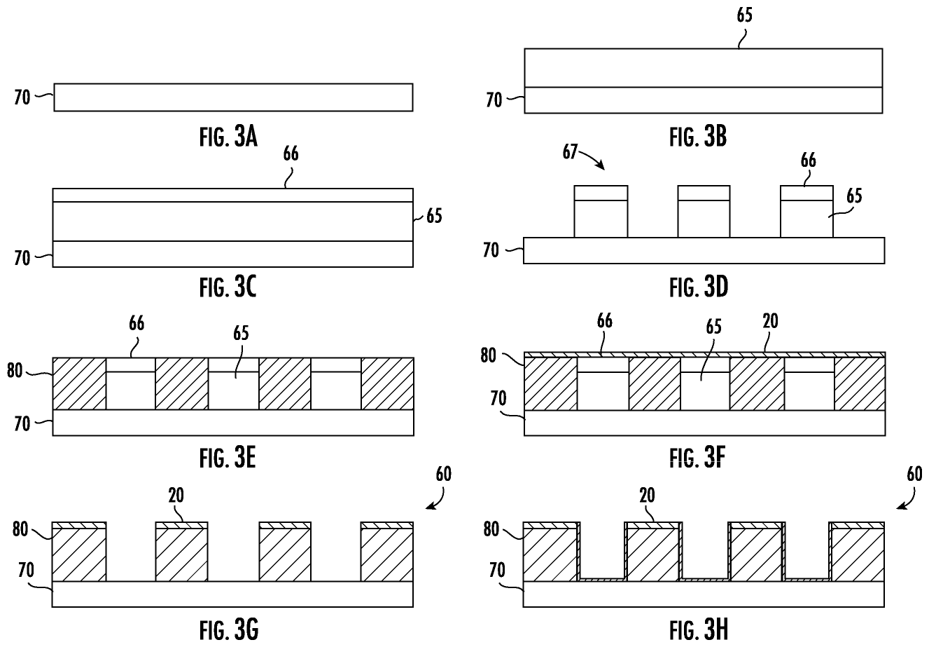

FIGS. 2A-2F and 3A-3F show more detailed illustrations of the process for creating the template 60.

The first process creates the template 60 using a resist 61, such as hydrogen silsesquioxane (HSQ).

First, as shown in FIG. 2A, a surface 70 is provided. The surface 70 may be made lyophilic through plasma treatment. As shown in FIG. 2B, a resist 61 is spun on the lyophilic surface 70. The thickness of the resist 61 may be determined based on the desired size of the micro or nanocrystals. The resist 61, which can be positive or negative, may display resistance to growth solvents after development. Such resistance can be achieved through the choice of resist 61 and/or post-development baking (i.e., to crosslink resist).

In one embodiment, hydrogen silsesquioxane (HSQ) is used as the resist 61 and is applied to the surface 70. The template 60 is fabricated using electron-beam lithography in the resist 61. The resist 61 is exposed, but not developed, creating exposed portions 62, as shown in FIG. 2C. Then, as shown in FIG. 2D, an asymmetric surface wetting is achieved using a two-step surface functionalization with self-assembled fluorinated molecular monolayers (for example, 1H, 1H, 2H, 2H-perfluorooctyl-trichlorosilane or 1H, 1H, 2H, 2H-perfluorodecyltriethoxysilane). Note that other variations of fluoromolecules may also be utilized. The first functionalization step is performed in vapor-phase upon HSQ electron-beam exposure such that the surface 20 of the resist 61 assumes a large contact angle with the perovskite precursor solution 30. The large contact angle may be greater than 50°. In some embodiments, the large contact angle may be 70°. In other words, the first functionalization step causes the resist 61 to become lyophobic by the formation of a lyophobic surface 20 on top of the resist 61. Next, the resist is developed, as shown in FIG. 2E. Once the HSQ is developed, the lyophilic interior of the well 10 is exposed.

The interior of the well 10 is lyophilic because it was not subjected to the first functionalization step. As shown in FIG. 2F, the wetting properties of the well 10 is then further tuned through a second, shorter, molecular growth step. This second functionalization step is used to tune the inside surface of the well 10 to slightly reduce its level of lyophilicity. This second molecular growth step may use the same self-assembled fluorinated molecular monolayers that were used in the first functionalization step, except for a shorter duration. The latter helps control the precursor solution distribution within the well 10 and its drying dynamics. This also helps determine the contact angle, as described below. This completes the formation of the template 60.

While the above disclosure describes a template made using treated HSQ, other embodiments e also possible. One such alternate embodiment is shown in FIGS. 3A-3H.

In this embodiment, as shown in FIG. 3A, a surface 70 is provided. This surface may be a lyophilic surface. Then, as shown in FIG. 3B, a first resist 65, such as PMMA, is deposited on the surface 70 and then baked. After this, as shown in FIG. 3C, a second resist 66, such as HSQ, is then deposited on the first resist 65. The second resist 66 is exposed and developed, which exposed portions of the first resist 65. The exposed portions of the first resist 65 are then etched. The result, which is shown in FIG. 3D, is a plurality of pillars 67, made of the stacked first resist 65 and second resist 66. The locations and dimensions of these pillars 67 will ultimately become the wells 10. Next, silicon dioxide 80 is deposited on the substrate as shown in FIG. 3E. The silicon dioxide 80 is then subjected to the first functionalization step to increase its lyophobicity. This creates a lyophobic surface 20 on the top of the pillars 67 and the silicon dioxide 80, as shown in FIG. 3F. The pillars 67 are then lifted off, such as by using acetone. As shown in FIG. 3G, this leaves a template 60 that is made up of lyophobic silicon dioxide with a plurality of wells 10, similar to the template shown in FIG. 1A. The second functionalization step may then be applied, as shown in FIG. 3H.

Thus, the template 60 may be a resist, such as HSQ, or a dielectric material, such as silicon dioxide. However, the template 60 is not limited to resist and dielectric materials. For example, in certain embodiments, the template 60 may be created from a metal material or a different conductive material. In this scenario, a lateral junction may be created, in which conductive surfaces are the opposite walls of the well. This may allow a hybrid dielectric/metal sample where the metal wires form the surface topography needed-serving both as the surface structure to help the nanocrystal formation but also as the active device component to make electrical contact to the nanocrystal. In this way, the nanocrystals are formed self-aligned into other device structures.

In some embodiments, all fabrication steps are performed at low temperatures (<100° C.), so preexisting structures are not damaged by the crystal fabrication protocol. Additional fabrication can also be conducted after growth.

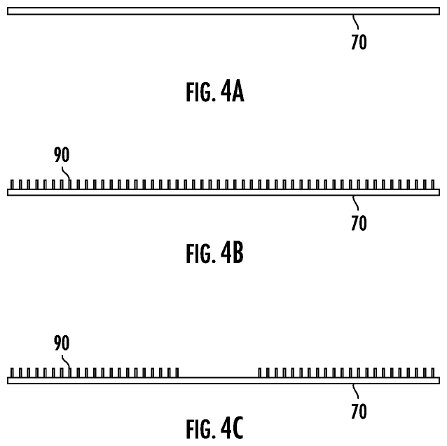

Thus, the creation of the template 60 is not limited to a particular embodiment. Various techniques may be used to create the template. Further, in some embodiments, a template may not be used. FIGS. 4A-4C shows one such embodiment.

In FIG. 4A, a surface 70 is provided. This surface 70 is made lyophilic through plasma treatment. Next, as shown in FIG. 4B, a lyophobic molecule 90 is grown on the surface. This lyophobic molecule 90 (or thin film) is then patterned using techniques including thermal scanning probe lithography, e-beam lithography, or focused-ion beam patterning, as shown in FIG. 4C. Through this step, the molecular (thin film) coating in the patterned regions will undergo degradation or surface transformation to generate or expose a lyophilic surface.

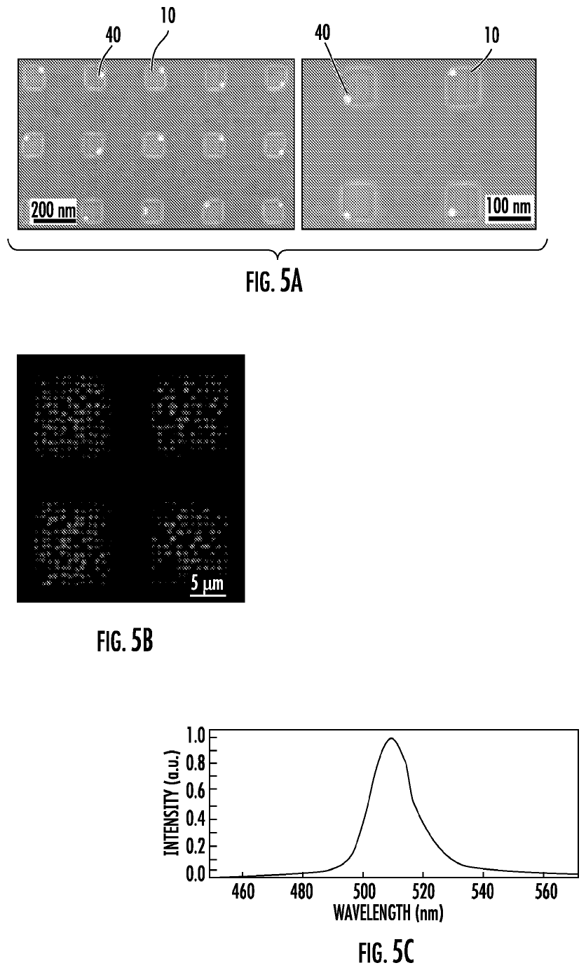

FIGS. 5A-5C show example perovskite nanocrystals using the fabrication scheme shown in FIGS. 2A-2F. The nanocrystals 40 shown are CsPbBr₃, however, this technique is versatile and can accommodate formation of other all-inorganic or organic-inorganic perovskites. Additionally, this technique is compatible with all materials, including insulators, metals and semiconductors, that can be formed through solution processing. FIG. 5A shows scanning electron microscope (SEM) images of the perovskite nanocrystals 40. FIG. 5B shows a photoluminescence (PL) map of an array of CsPbBr₃ nanocrystals. FIG. 5C shows the PL spectrum of an example nanocrystal.

As seen in FIG. 5A, this approach enables deterministic placement of the nanocrystals 40 confined to the wells 10. However, in the case of a square well, the crystal 40 may be located at any of the four corners. This is because, during solvent evaporation, a meniscus forms within the well 10. Crystals 40 nucleate at the meniscus minimum because this is the location at which the precursor concentration is locally highest. However, the pressure experienced at this meniscus minimum differs from that experienced in the remainder of the solution. This is due to interactions with the underlying surface 70. This pressure difference, referred to as the disjoining pressure (P_{d}), scales inversely with the liquid thickness (δ), given by P_{d}=A_{H}/6πδ³, where A_{H} is the Hamaker constant between the liquid and the underlying surface. As a result, because the thickness of the precursor solution 30 varies across the meniscus, a pressure gradient is created in the well 10. This pressure gradient then induces a directional force which guides the nanocrystal 40 from the region of lowest meniscus thickness to the region of highest meniscus thickness. For a square well, this region of highest meniscus thickness is found at each of the four corners. Consequently, since a square well has a symmetric meniscus, the nanocrystals 40 are equally likely to reside at any of the four corners. Therefore, the precision of the placement is dictated by the distance between the corners of the well.

In some embodiments, the precision of the placement may be improved by decreasing the well size. However, the minimum size of the well is determined by the resolution of the lithographic technique. A smaller well may also result in a smaller crystal 40 or the absence of a crystal 40. In other words, by making the well smaller, less solution is trapped in the well. This may adversely affect crystal size. Additionally, if the wells become too small, depending on the surface wettability, the wells 10 may remain at least partially unfilled with solution. Therefore, no crystal 40 may form in that well 10. Consequently, other mechanisms, other than well size, are needed to refine the precision of the crystal placement.

Precise control of the position of crystal formation may be achieved through the shape, orientation, and relative location of templates on the substrate. As shown in FIG. 5A, the symmetrical shape of the well allows the crystal to form at any of the four corners.

The pressure gradients described above may be advantageously exploited to achieve precise placement of the crystal at a predetermined location. To achieve this, the meniscus is engineered to have an asymmetric form. In this way, the forces induced by the pressure gradient includes one dominant force that guides the crystal 40 in a preferential direction. The meniscus shape can be tuned using the precursor solution contact angle to the well sidewalls, and the well geometry.

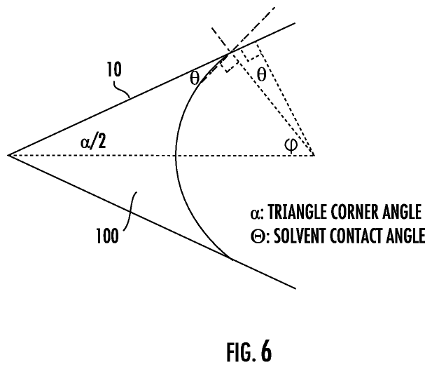

FIG. 6 shows a well 10 having an interior angle α, where the meniscus 100 forms an angle θ with the wall of the well 10. Referring to the triangle shown in FIG. 6, it can be seen that

$$\frac{α}{2} + φ + \frac{π}{2} + θ = π .$$

The critical contact angle is that angle which is approached as φ goes to 0. The critical contact angle, θ_{c}, is defined as

$$\frac{π}{2} - \frac{α}{2} .$$

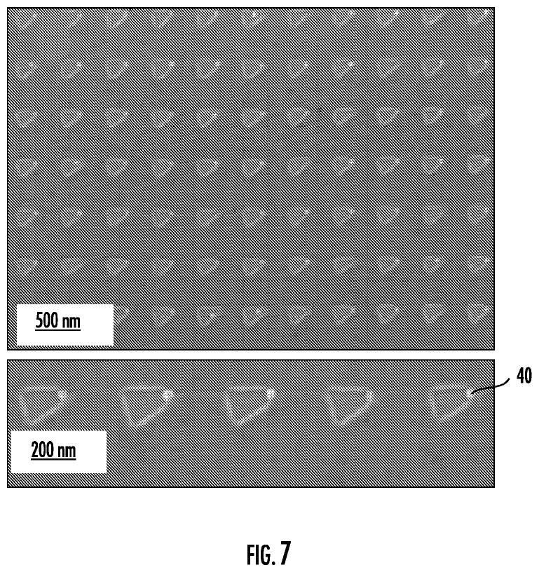

when the contact angle is smaller than a critical contact angle θ_{c}, the meniscus 100 changes from spanning the entire well pinned at the sidewalls to having some liquid remaining at the corners as it propagates into the well. The menisci at the corners may be referred to as the arc menisci, while the central region may be referred to as the main terminal meniscus. Depending on the corner geometry, the critical angle for the arc meniscus formation varies. Thus, by using an asymmetrically shaped well, an asymmetric meniscus can be obtained with different amounts of liquid trapped at each corner. This is illustrated in the triangular well of FIG. 7. Note that the crystal is disposed in the same location in each of these triangular wells.

In one experiment, wells shaped like an equilateral triangle, a first isosceles triangle with corner angles (44°, 68°, 68°) and a second isosceles triangle with corner angles (20°, 80°, 80°) were created, each having the same volume of precursor solution 30 and the same height. The surface functionalization steps were designed such that the wells had a contact angle of 50° to the precursor solution. It was found that an asymmetric well geometry favors formation of single crystals with the yield improving to 80% for the well that was shaped as an isosceles triangle having corner angles or (20°, 80°, 80°) template. Thus, in certain embodiments, the triangular well is an isosceles triangle where one of the angles is less than 45° and the contact angle is 50° or more. In some embodiments, one of the angles is 30° or less and the contact angle is 50° or more.

Additionally, as with the case of the square well, the symmetry in the equilateral triangular well results in near equal distribution of the nanocrystals at the three corners. Regarding the isosceles triangle shaped wells, the nanocrystal is preferentially positioned in the smallest angle. Specifically, in one experiment, roughly 67% and 89% of the nanocrystals are disposed in the smallest corner of the (44°, 68°,68°) and (20°, 80°, 80°) isosceles triangles, respectively. Note that as the corner angle is made smaller, an improved positional accuracy is achieved. In some embodiments, the position accuracy may be less than 50 nm.

The results related to the isosceles triangle shaped well with corner angles of (20°, 80°, 80°) confirms the significance of the critical contact angle. Note that the two larger corner angles have a 50° critical contact angle (θ_{c1}), while the 20° corner angle has an 80° critical contact angle (θ_{c2}). Note that if the wells are processed to have a contact angle (θ) that satisfies the equation, θ_{c1}≤θ<θ_{c2}, the crystal will preferentially be positioned in the smallest angle. This relationship maximizes the extent to which the crystal is preferentially directed toward one corner, allowing for higher yield deterministic positioning.

In addition to controlling the placement of a crystal 40, the size of the crystal may also be controlled using this technique. One approach to controlling crystal size is by controlling the precursor solution concentration, where a higher concentration yields larger particles. However, this approach is limited as the concentration needs to be maintained close to the saturation regime to facilitate the crystal formation process.

Alternatively, the nanocrystal size can be controlled by modifying the well size to change the volume of precursor solution disposed in a well. This can be readily implemented through the lithographic patterning of the template. Further, this approach allows different sized crystal to be formed on the same substrate by varying the dimensions of the various wells.

Note that well volume may be changed by varying the area of the well, the height of the well, or both parameters. In one experiment, wells having thicknesses of 22, 28, and 36 nm and areas of 150², 200² and 250² nm² were fabricated as isosceles triangle shaped wells with corner angles of (20°, 80°, 80°). Thus, nine different well dimensions were created. Note that the area of the wells is not limited by this disclosure. In some embodiments, the wells may have an area of 1000² nm² or more. In some embodiments, the wells may have an area of 10 μm² or more. Similarly, the thickness of the template is not limited by this disclosure and may be up to 1 μm. It was found that wells of greater volume generally resulted in larger crystals. However, it was also found that increasing the area of the well may lead to an increased incidence of multiple crystals in a single well. However, this phenomenon was less likely when the volume was increased by increasing the thickness of the well. Furthermore, the number of crystals in a well may also be controlled by adjusting the precursor solution contact angle to the well. Fewer multi-crystal events occur with a lower contact angle. Thus, by manipulating the well area, the well thickness and the contact angle, the size and number of particles may be controlled.

Furthermore, the crystal's optical properties may be modified by varying the size of the crystal. The photoluminescence (PL) emission spectra were collected for the nanocrystals formed in the different well volumes. The results show that the peak photoluminescence emission blue-shifts to higher energies as the crystal size decreases.

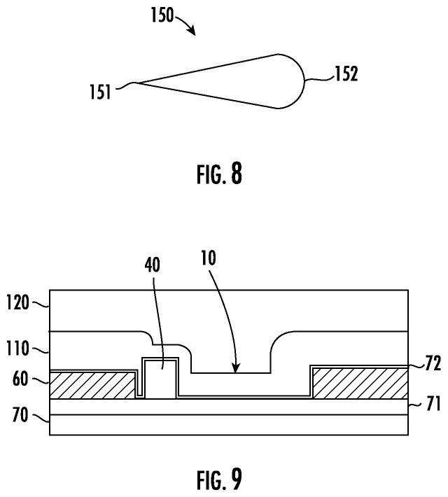

While the above disclosure describes wells in the shapes of regular polygons, other shapes are also possible. For example, a tear drop shaped well 150, such as that shown in FIG. 8, may be used. The tear drop shaped well 150 may have one small corner angle 151 and a larger hemispherical perimeter 152. The small corner angle 151 may be less than 30°. This asymmetric meniscus design induces a force directed toward the hemispherical portion of the tear drop shaped well 150, where the crystal is preferentially formed. Other shaped wells may also be used and the shape is not limited by this disclosure.

In addition, more complex topologies may be used. For example, the template may include wells that are a combination of different shapes in different geometries and orientations. Further, the organization of the wells 10 does not need to be periodic. Thus, the wells may be arranged spatially in any pattern, or randomly, if desired.

Also, the wells 10 do not need to be made in any particular geometry. As noted above, the edges/corner/spacing between device structures (for example wires/electrodes or other features) may be used as the topography needed to confine the precursor solution.

The technique described herein may be used to create an array of LEDS. FIG. 9 shows a cross-sectional view of the substrate with the crystal. In this embodiment, the surface 70 may be glass, with indium tin oxide (ITO) 71 disposed on the glass, although other contacts and substrates, such as metals on glass or silicon may be used. The template 60 may be formed using silicon dioxide, although other materials may be used. Crystals 40 are formed in the wells 10 of the template 60. In this embodiment, the wells 10 may be tear drop shaped, although other shapes may be utilized. Once the crystals 40 are formed, a thin layer of PMMA 72 is deposited over the substrate. Next, a 2,2′,2″-(1,3,5-benzinetriyl)-tris(1-phenyl-1-H-benzimidazole) (TPBi) electron-transport layer 110 is thermally evaporated on the substrate. Lastly, a conductive layer 120, such as a LiF/Al top contact, is thermally evaporated. In this way, there is a conductive path from each nanocrystal 40 to a conductive layer.

While the above disclosure describes a halide perovskite crystal, this technique is also applicable to other perovskite crystals. Additionally, this technique is applicable to any compound that can be formed into crystals through solution processing.

This disclosure shows arrays of nanoLEDS. These LEDs may be individually addressable. Further, the disclosure is not limited to arrays of the same type of device. For example, this technique may be used to allow various devices forming on the same surface in a single step nanocrystal formation. For example, this approach may be used to create a mixture of nanoLEDs, laser and/or transistors.

This system and method have many advantages. Perovskite nanocrystals can be applied to developing optoelectronic devices including solar cells, lasers, light-emitting diodes, photodetectors, neuromorphic devices, light emitting transistors and single photon sources. Furthermore, perovskite nanocrystals have demonstrated unique opportunities in emerging quantum information technologies including for quantum computing, communication, memory, sensing and metrology. For device integration to be effective, crystals of these materials need to be positioned with high positioning accuracy with respect to electrical or optical structures and with high throughput. This is not feasible with conventional techniques and is uniquely made possible using the method disclosed herein. This method enables in-situ, deterministic growth of perovskite nanocrystals of various structural and chemical compositions and sizes, and is applicable to diverse perovskite-based technologies.

Moreover, the method described herein may be incorporated into traditional semiconductor processes, as the surface on which the template is disposed may be a semiconductor wafer. This semiconductor wafer may already have been processed to incorporate one or more layers of devices and junctions, or may be an unprocessed wafer.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A method of producing perovskite crystals in-situ, comprising:
creating an asymmetrically wetting template on a surface, wherein the template comprises a plurality of wells; and
disposing a perovskite precursor solution comprising a metal halide perovskite in the plurality of wells;
wherein, after evaporation, a perovskite crystal is disposed in one or more of the plurality of wells.

2. The method of claim 1, wherein the perovskite precursor solution comprises perovskite precursor ions dissolved in a solvent.

3. The method of claim 2, wherein the perovskite precursor solution further comprises ligands that passivate the surface of the perovskite crystal or polymers that encapsulate particles during formation.

4. The method of claim 1, further comprising encapsulating the perovskite crystal by deposition of a polymer, ligand, or oxide layer by a solution- or vapor-phase process.

5. The method of claim 1, wherein the asymmetrically wetting template comprises a lyophobic surface.

6. The method of claim 5, wherein the lyophobic surface is formed by exposing the template to a first functionalization step using self-assembled fluorinated molecular monolayers.

7. The method of claim 5, wherein the plurality of wells are lyophilic, and a degree of lyophilicity of the plurality of wells is tuned by exposure to a second functionalization step using self-assembled fluorinated molecular monolayers.

8. (canceled)

9. The method of claim 1, wherein the wells are shaped such that the perovskite crystal preferentially forms at a predetermined location within the wells.

10. The method of claim 9, wherein the wells are triangular shaped or tear drop shaped.

11. (canceled)

12. (canceled)

13. (canceled)

14. The method of claim 1, wherein the template comprises a resist, a dielectric material or a metal.

15. The method of claim 1, wherein the asymmetrically wetting template is created by:
applying a resist to the surface;
exposing the resist;
performing a first functionalization step using self-assembled fluorinated molecular monolayers on the exposed resist; and
developing the resist to create the plurality of wells, wherein a top surface of the resist is lyophobic.

16. The method of claim 1, wherein the asymmetrically wetting template is created by:
applying a first resist to the surface;
applying a second resist on the first resist;
patterning the first resist and second resist to create a plurality of pillars;
depositing a dielectric material in spaces between the plurality of pillars;
performing a first functionalization step using self-assembled fluorinated molecular monolayers on the dielectric material and the plurality of pillars; and
lifting off the plurality of pillars;
wherein, after the lifting off, the dielectric material has the plurality of wells and a lyophobic top surface.

17. The method of claim 1, wherein a size of the perovskite crystal is controlled by varying a volume of the wells.

18. (canceled)

19. A method of fabricating an LED Array, comprising:
creating an asymmetrically wetting template on a substrate, wherein the template comprises a plurality of wells;
disposing a perovskite precursor solution comprising a metal halide perovskite in the plurality of wells;
wherein, after evaporation, a perovskite nanocrystal is disposed in one or more of the plurality of wells;
applying an electron transport layer after the perovskite nanocrystal is formed; and
disposing a conductive layer on the electron transport layer.

20. The method of claim 19, wherein the substrate comprises indium tin oxide on glass.

21. (canceled)

22. A method of producing nano or microcrystals in-situ, comprising:
creating an asymmetrically wetting template on a surface, wherein the template comprises a plurality of wells; and
disposing a precursor solution comprising precursor ions in a solvent in the plurality of wells;
wherein, after evaporation, the nano or microcrystal is disposed in one or more of the plurality of wells.

23. The method of claim 22, wherein the asymmetrically wetting template comprises a lyophobic surface.

24. The method of claim 23, wherein the lyophobic surface is formed by exposing the template to a first functionalization step using self-assembled fluorinated molecular monolayers.

25. The method of claim 23, wherein the plurality of wells are lyophilic, and a degree of lyophilicity of the plurality of wells is tuned by exposure to a second functionalization step using self-assembled fluorinated molecular monolayers.

26. (canceled)

27. The method of claim 22, wherein the wells are shaped such that the nano or microcrystal preferentially forms at a predetermined location within the well.

28. (canceled)
